(19) United States
(12) Patent Application Publication
(10) Pub. No.: US 2008/0290435 A1
(43) Pub. Date: Nov. 27, 2008

(54) WAFER LEVEL LENS ARRAYS FOR IMAGE SENSOR PACKAGES AND THE LIKE, IMAGE SENSOR PACKAGES, AND RELATED METHODS

(75) Inventors: Steve Oliver, Boise, ID (US); Kyle K. Kirby, Eagle, ID (US); Warren M. Farnworth, Nampa, ID (US); William M. Hiatt, Eagle, ID (US); Salman Akram, Boise, ID (US)

Correspondence Address: TRASK BRITT, P.C./ MICRON TECHNOLOGY, P.O. BOX 2550, SALT LAKE CITY, UT, 84110, US

(73) Assignee: MICRON TECHNOLOGY, INC., Boise, ID (US)

(21) Appl. No.: 11/751,206

(22) Filed: May 21, 2007

(51) Int. Cl. H01L 31/0232; B29D 11/00; H01L 21/00

(52) U.S. Cl. 257/432; 264/1.1; 438/65; 257/E31.127; 257/E21.001

(57) ABSTRACT

Image sensor packages, lenses therefore, and methods for fabrication are disclosed. A substrate having through-hole vias may be provided, and an array of lenses may be formed in the vias. The lenses may be formed by molding or by tenting material over the vias. An array of lenses may provide a color filter array (CFA). Filters of the CFA may be formed in the vias, and lenses may be formed in or over the vias on either side of the filters. A substrate may include an array of microlenses, and each microlens of the array may correspond to a pixel of an associated image sensor. In other embodiments, each lens of the array may correspond to an imager array of an image sensor. A wafer having an array of lenses may be aligned with and attached to an imager wafer comprising a plurality of image sensor dice, then singulated to form a plurality of image sensor packages.

### FIELD OF THE INVENTION

The present invention relates to lenses for image sensor packages, wafer level structures in the fabrication thereof and components and fabrication methods therefore. More particularly, the invention pertains to methods for fabricating lenses at a wafer or other bulk substrate level for packaging radiation sensing or emitting devices, as well as cameras and the like including the same, and lenses at the wafer or other bulk substrate level in the fabrication.

### BACKGROUND OF THE INVENTION

State of the Art: Semiconductor die-based image sensors are well known to those having skill in the electronics/photonics art and, in a miniaturized configuration, are useful for capturing electromagnetic radiation (e.g., visual, IR or UV) information in digital cameras, personal digital assistants (PDA), internet appliances, cell phones, test equipment, and the like, for viewing, further processing or both. For commercial use in the aforementioned extremely competitive markets, image sensor packages must be very small. For some applications, a package of a size on the order of the semiconductor die or chip itself or a so-called “chip scale” package, is desirable if not a requirement.

While traditional semiconductor devices, such as processors and memory, are conventionally packaged in an opaque protective material, image sensors typically comprise a light wavelength frequency radiation-sensitive integrated circuit (also termed an “optically sensitive” circuit or “optically active region”) fabricated on the active surface of a semiconductor die and covered by an optically transmissive element, wherein the optically sensitive circuit of the image sensor is positioned to receive light radiation from an external source through the optically transmissive element. Thus, one surface of the image sensor package conventionally comprises a transparent portion, which usually is a lid of light-transmitting glass or plastic. For photographic or other purposes requiring high resolution, the chip is positioned to receive focused radiation from an optical lens associated therewith. The image sensor may be one of a charge coupling device (CCD) or a complementary metal oxide semiconductor (CMOS). The optically sensitive circuit of each such sensor conventionally includes an array of pixels containing photo sensors in the form of photogates, phototransistors or photodiodes, commonly termed an “imager array.”

When an image is focused on the imager array, light corresponding to the image is directed to the pixels. An imager array of pixels may include a micro-lens array that includes a convex micro-lens for each pixel. Each micro-lens may be used to direct incoming light through a circuitry region of the corresponding pixel to the photo sensor region, increasing the amount of light reaching the photo sensor and increasing the fill factor of the pixels. Micro-lenses may also be used to intensify illuminating light from pixels of a non-luminescent display device (such as a liquid crystal display device) to increase the brightness of the display, or to form an image to be printed in a liquid crystal or light emitting diode printer, or even to provide focusing for coupling a luminescent device or receptive device to an optical fiber.

Various factors are considered in the design and manufacture of image sensor packages. For example, the extent to which the packages can be at least partially, if not completely, fabricated at the wafer level is a substantial cost consideration. Furthermore, if the package design or fabrication approach, even if conducted at the wafer level, necessitates that all of the image sensor semiconductor dice located thereon be packaged regardless of whether a significant number of the dice are defective, a substantial waste of materials results. Also, the package lenses must be carefully positioned relative to the optically sensitive circuit on each of the dice to achieve uniformly high quality imaging while precluding entry of moisture and other contaminants into the chamber defined between the optically sensitive circuitry and the lens.

Despite advances in the state of the art of image sensor packaging, there remains a need for a high-yield packaging technique which may be effected at a wafer level and provides high quality image sensor packages.

### BRIEF DESCRIPTION OF THE SEVERAL VIEWS OF THE DRAWINGS

In the drawings, which depict embodiments of the present invention, and in which various elements are not necessarily to scale:

FIGS. 1A-1C depict acts in the fabrication of one embodiment of a lens of the present invention;

FIG. 2 shows one embodiment of a wafer level lens array of the present invention;

FIG. 3 shows the wafer level lens of FIG. 2 with an imager wafer;

FIG. 4 illustrates a plurality of singulated imager packages;

FIG. 5A depicts another embodiment of an imager package according to the present invention;

FIGS. 5A through 5C depict acts in the formation of the imager package of FIG. 5A;

FIG. 6A shows another wafer level lens array of the present invention;

FIG. 6B shows still another wafer level lens array of the present invention;

FIG. 7 shows a lens array of microlenses of the present invention;

FIG. 8 shows yet other wafer level lens array of the present invention;

FIGS. 9A through 9C each show an embodiment of a lens of the present invention;

FIG. 10 shows still another embodiment of a imager package according to the present invention;

FIG. 11 schematically depicts an embodiment of a lens stack of the present invention; and

FIG. 12 is a simplified block diagram illustrating an embodiment of an imaging system that includes a lens as shown and described with respect to FIGS. 2-11.

### DETAILED DESCRIPTION OF THE INVENTION

Referring in general to the accompanying drawings, various aspects of the present invention are illustrated to show embodiments of semiconductor package structures and methods for assembly of such package structures. Common elements of the illustrated embodiments are designated with like reference numerals. It should be understood that the figures presented are not meant to be illustrative of actual views of any particular port ion of a particular semiconductor package structure, but are merely idealized schematic representations which are employed to more clearly and fully depict the invention.

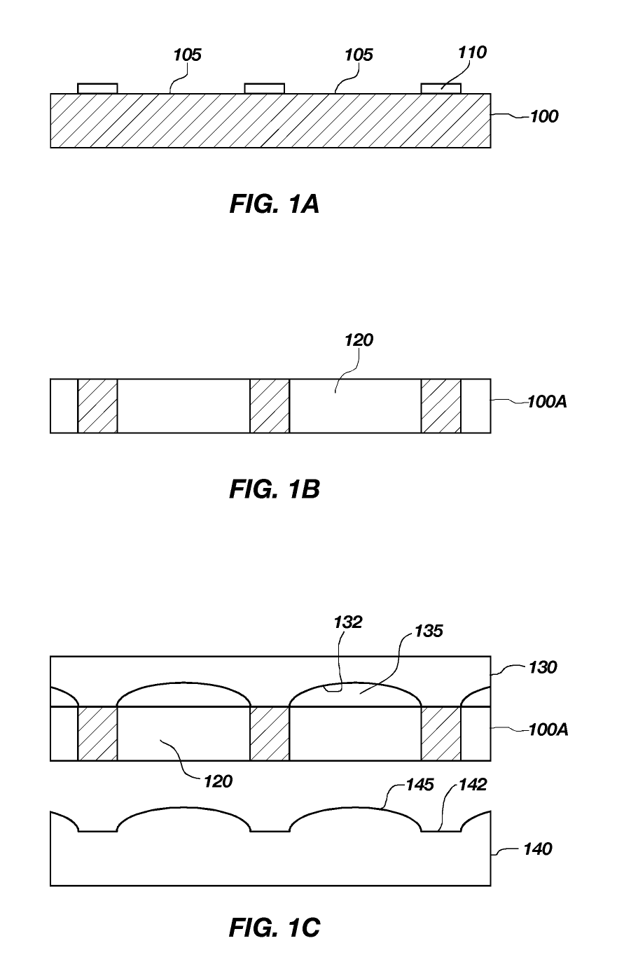

FIGS. 1A through 1C illustrate a method of forming a lens array at the wafer or other bulk substrate level. A substrate 100 is provided with patterned photoresist 110 thereon. The substrate 100 may be sized and shaped like a wafer for use in processing by existing semiconductor fabrication equipment. The substrate 100 may comprise, by way of example, a silicon or borosilicate material. As used herein, the term “wafer” encompasses conventional wafers, bulk semiconductor substrates such as silicon-on-insulator (SOI) substrates as exemplified by silicon-on-glass (SOG) substrates and silicon-on-sapphire (SOS) substrates. The substrate 100 may be a wafer which has been determined to be unsuitable for its original purpose due to damage or defects therein. Thus, a recycled wafer may be used as the substrate 100.

The photoresist 110 may be patterned by known methods, for example, photolithographic methods of masking, patterning, developing and etching. Via locations 105 may be exposed on the substrate 100 through the patterned and developed photoresist 110. The substrate 100 may be substantially anisotropically etched by a wet or dry (RIE) etch technique suitable for the material of substrate 100 to form vias 120 in the exposed locations 105. The photoresist 110 may be removed to form the substrate 100A having vias 120, as shown in FIG. 1B. The vias 120 extend through the resulting substrate 100A. Other methods of forming vias 120, for example by laser ablation or drilling, are also within the scope of the invention.

Turning to FIG. 1C, mold plates 130 and 140 may be provided. The first mold plate 130 may include concave portions 135 at spaced apart locations on a surface 132 thereof. The concave portions 135 may be sized, configured and spaced to align with the vias 120 of the substrate 110A. The second mold plate 140 may include protruding, convex portions 145 at spaced apart locations on a surface 142 thereof. The convex portions 145 may be sized, configured and spaced to align with and be received within the vias 120 of the substrate 110A.

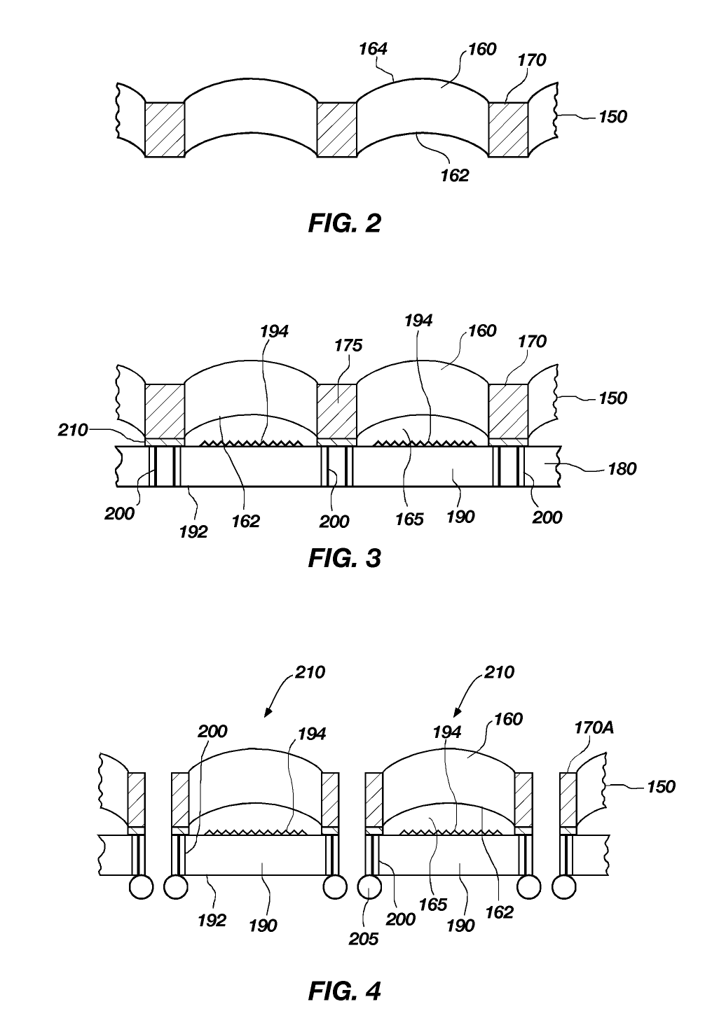

Lens material in a flowable or otherwise deformable state, for example, a polymer such as a polyimide, may be introduced into the vias 120 of the substrate 110A. A photopolymer curable, for example, by exposure to ultraviolet (UV) light may also be employed. The lenses 160 (see FIG. 2) may be formed, by example, by conventional injection molding or transfer molding techniques. A glass material, such as silicon dioxide, borosilicate glass, phosphosilicate glass, or borophosophosilicate glass, may also be used as a lens material. The coefficient of thermal expansion (CTE) of the tense material may be selected to reasonably match that of the substrate. Thus, thermal mismatch problems at temperatures and over temperature ranges encountered in fabrication, test and use of the semiconductor packages may be avoided.

The first mold plate 130 and the second mold plate 140 may be aligned with the substrate 100A, and the lenses 160 may be formed using injection or transfer molding, or embossing, or UV imprint lithography. Alternatively, the first mold plate 130 may be aligned with the substrate 100A, and the vias 120 may be substantially filled with the lens material, the first mold plate 130 and substrate 100A being inverted from the position shown in FIG. 1C. The second mold plate 140 may then be pressed against the substrate 100A, sandwiching the substrate 100A between the first mold plate 130 and the second mold plate 140 and pressing the flowable or deformable lens material into the concave portions 135 of the first mold plate 130 between the first mold plate 130 and the second mold plate 140. The mold plates 130, 140 may be used to form the lenses from the lens material to their final shape in a stamping operation. The mold plates 130, 140 may comprise, for example, silicon.

A step and repeat method may be employed to individually form the lenses 160. Polymer may be stamped and cured from one or both sides of the substrate 100A and the wafer is moved to the next lens location for a stamp and cure. This method may be used to form a single lens, or to form an array of lenses 160 within the substrate 100A. A step and repeat method may reduce the cost of forming a full wafer mold, and smaller, high accuracy molds are easier to make.

The Lens material within the vias 120 of the substrate and the concave portions 135 of the first mold plate 130 may be solidified, for example by applying pressure, light, heat or cold, depending upon the lens material selected, to form a plurality of lenses 160, each lens positioned in a via 120 of the substrate 110A. FIG. 2 depicts a wafer-level lens array 150 with lenses 160 in a lens array substrate 170. The lens array substrate 170 may be formed using the method described to form the substrate 100A of FIG. 1B, and may be configured to have a size and peripheral shape corresponding to the diameter of a wafer used with conventional semiconductor fabrication equipment.

It may be desirable to form an asymmetric lens to enable a lens configuration having a desired focal length. The lenses 160 of the wafer-level lens array 150 shown in FIG. 2 are asymmetric, with a convex surface 164 and an opposing, concave surface 162. It also may be desirable to form a double concave or double convex lens that may or may not have symmetrical profiles. The lens profile, whether concave or convex, spherical or aspherical, will depend on the optical design and the optical performance requirements of the lens system.

The wafer-level lens array 150 may be bonded to a through wafer interconnect (TWI) imager wafer 180. The TWI imager wafer 180 may include an array of semiconductor dice in the form of image sensor dice or other optically active dice 190, the term “optically active” encompassing any semiconductor die which is configured to sense or emit electromagnetic radiation. For example, the optically active dice 190 may comprise image sensor dice in the form of CMOS imagers, each having an optically sensitive circuit or optically active region comprising an imager array 194.

The TWI imager wafer 180 may further include conductive vias 200 therethrough for connecting the optically sensitive circuit of comprising imager array 194 each image sensor die 190 by the back side 192 thereof with external circuitry. The vias 200 may, optionally, be spaced to align with the substrate material 175 of the lens array substrate 170 but in any case are located outside the “street” lines defined between individual image sensor dice 190 and along which the TWI imager wafer 180 is singulated, as described below.

The TWI imager wafer 180 may comprise silicon. The lens array substrate 170 may be borosilicate, which has a coefficient of thermal expansion (CTE) close to the COTE of silicon, reducing problems associated with CTE mismatch. Use of a lens array substrate 170 comprising a semiconductor material or a material of similar CTE provides a CTE, close, if not identical to, that of the semiconductor material of the TWI imager wafer, avoiding the severe mismatch of CTEs which occurs when a metal lens frame is employed, and associated stress on the assembly during thermal cycling experienced in normal operation of a image sensor device assembly.

The lens array substrate 170 may be bonded to the TWI imager wafer 180 by any suitable method, for example, fusion bonding, anodic bonding, or with an epoxy. Anodic bonding and fusion bonding are described in A. Berthold, et al., Low Temperature Wafer-To-Wafer Bonding for MEMS Applications, Proc. RISC/IEEE, 31-33, 1998 (ISBN 90-7346115-4), the disclosure of which is incorporated by reference herein. Anodic bonding may be used to join silicon-to-silicon, silicon-to-glass and glass-to-glass, wherein a high voltage (800V) electric field induces adhesion at about 300° C. Alternatively, a lower temperature fusion bonding method may be used, including a first surface etching step, rinse, nitric acid treatment, rinse, prebonding of the components under force, and annealing at a somewhat elevated (120° C.) but generally lower temperature than is employed for anodic bonding. Epoxy may be applied by screen printing, dispensing or pad printing methods. Spacer beads can be added to the epoxy to help accurately define the bondline gap and maintain uniformity across the wafer.

Processing the lenses at a wafer level enables the wafer-level lens array to be precisely aligned over a substrate having an array of image sensors in the form of image sensor dice 190 fabricated thereon. Because the entire wafer-level lens array and array of image sensor dice 190 are aligned together, the alignment is more precise than aligning each lens and image sensor individually. The wafer-level lens array 150 and the imager wafer 180 may both be fabricated and bonded together in the same clean room environment, which may reduce the incidence of particulate matter introduction between each lens and its associated image sensor die 190. Multiple wafer-level lens arrays 150 may be stacked over a single imager wafer. A stack of lenses may be necessary for optimal image projection on an image sensor device.

Turning to FIG. 4, the TWI imager wafer 180 may be singulated between image sensor dice 190 to form image sensor packages 210. The substrate material 175 of the lens array substrate 170 of wafer-level lens array 150 may be cut between the lenses 160 in a singulation step to produce a plurality of image sensor packages 210 from the wafer-level lens array substrate 170 and the TWI inner wafer 180. Each image sensor package includes a portion 170A of the substrate 170, surrounding the lens 160. The term “cutting” is used when referring to singulation as such may be conventionally effected by using, for example, a wafer saw, but will be understood to include mechanical or water sawing, etching, laser cutting or other method suitable for severing the material 175 of the lens array substrate 170 and the TWI imager wafer 180.

Alternatively, the waferlevel lens array substrate 170, or a stack thereof, may be singulated or diced for single die placement on a TWI wafer. One advantage of this method is that the yield of the lens wafer die is not compounded by the yield of the imager wafer.

The concave surface 162 of the lens 160 may be oriented to face the TWI imager wafer 180 and provide a cavity or chamber 165 comprising an air, gas, or a vacuum gap between the concave lens surface 162 and the semiconductor die 190. Any suitable material with a refractive index less than that of the lens material may be employed for filling the cavity 165. The lens 160 may be sized, shaped, and otherwise configured to focus and/or collimate radiation (e.g., visible light) onto the optically active region of the image sensor die 190.

The image sensor packages 210 may each include a plurality of external electrical conductors 205. The external electrical conductors 205 may comprise discrete conductive elements in the form of conductive bumps, balls, studs, columns, pillars or lands. For example, solder balls may be formed or applied as external electrical conductors 205, or conductive or conductor-filled epoxy elements. The external electrical conductors 205 may be in communication with the optically active regions of semiconductor die 190 through conductive vias 200. For example, the through wafer interconnect imager wafer I 80 may include a redistribution layer (RDL) of circuit traces on the back side surface thereof in communication with conductive vias 200 therethrough. In another approach, external electrical conductors 205 may be formed or disposed directly over conductive vias 200. In yet another approach, no external electrical conductors 205 are employed, and conductive vias 200 or traces of an RDL may be placed in direct contact with conductors of higher-level packaging. Thus, electrical signals may be transferred between the optically active region of each semiconductor die 190 and external components (not shown) through conductive vias 200 and, optionally, the external electrical conductors 205. Any arrangement of suitable external electrical connectors 205 may be electrically connected to the image sensor die 190 to provide a particular package configuration, including a ball-grid array (BGA), a land grid array (LGA), a leadless chip carrier (LCC), a quad flat pack (QFP), quad flat no-lead (QFN) or other package type known in the art.

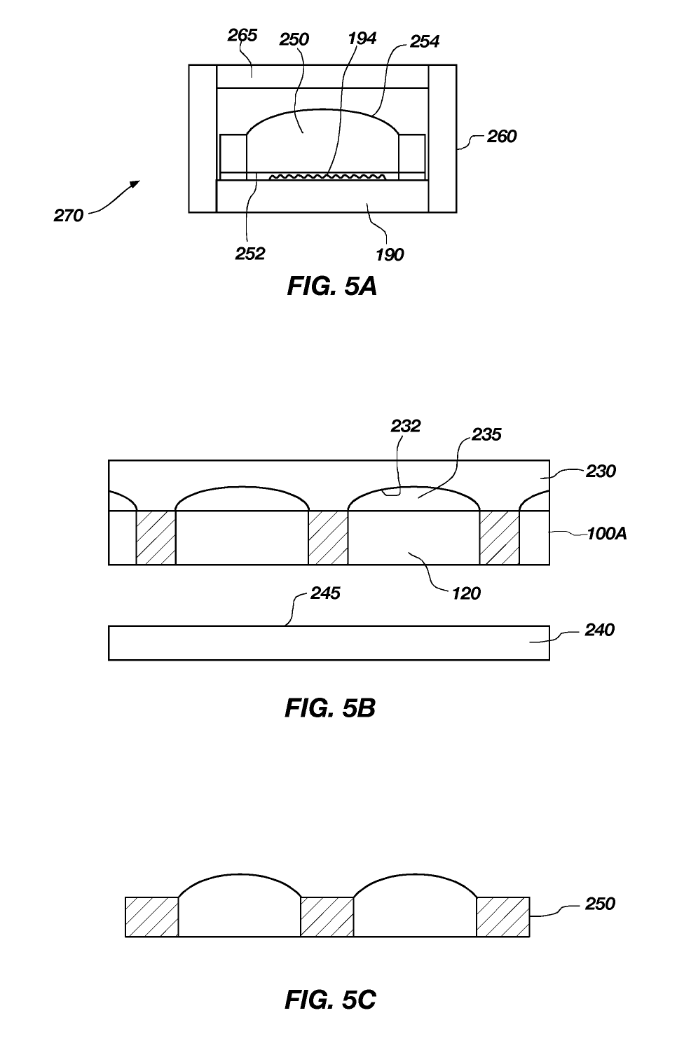

The lenses 160 of the array may, as associated with each image sensor die 190, be used as a field flattening lens 250 as shown in the packaged image sensor 270 shown in FIG. 5A. The field flattening lens 250 may be plano-convex, or planar on one side 252 and convex on the opposite side 254. The planar side may be positioned adjacent to the image sensor die 190. The image sensor die 190 and field flattening lens 250 may be packaged within a conventional imager package 260. The package 260 may include a window 265, also known as a cover glass. The window 265 is shown as being generally rectangular, but is not limited to such a shape and other polygonal shapes, as well as circular and nonplanar window shapes, may be employed. The window 265 may be formed of glass or other transparent or radiation-transmissive material such as a polymer. It may be formed of several layers and may be configured to selectively block radiation in a particular wavelength region, e.g., UV, infra-red, etc. The window 265 may be fabricated to be of high optical quality to provide uniform transmission therethrough of radiation over the entire usable field of the optically active region of the semiconductor device 190.

One advantage of a packaged image sensor 270 which includes a field flattening lens is that the external lens of an imaging system which includes the image sensor 270 will not need to include a field flattening lens. The large radius of curvature of the field flattening lens of the packaged image sensor 270 enables an external lens to be used which does not include a field flattening lens.

The field flattening lens 250 may be formed using the methods described hereinabove with respect to FIGS. 1A through 1C. Turning to FIG. 5B, mold plates 230 and 240 may be provided. The first mold plate 230 may include concave portions 235 at spaced apart locations in a surface 232 thereof. The concave portions 235 may be configured to align with the vias 120 of the substrate 100A. The second mold plate 240 may include a substantially planar surface 245. Flowable or deformable lens material, for example, a polymer such as polyimide or a photopolymer, may be introduced into the vias 120 of the substrate 100A. A glass material may also be used as a lens material. The lens material within the vias 120 of the substrate and the concave portions 235 of the first mold plate 230 may be solidified to form an array of plano-convex lenses 250, as shown in FIG. 5C. The array of plano-convex lenses 250 may be secured to an imager wafer, and singulated to form a plurality of image sensor packages 270 as previously described.

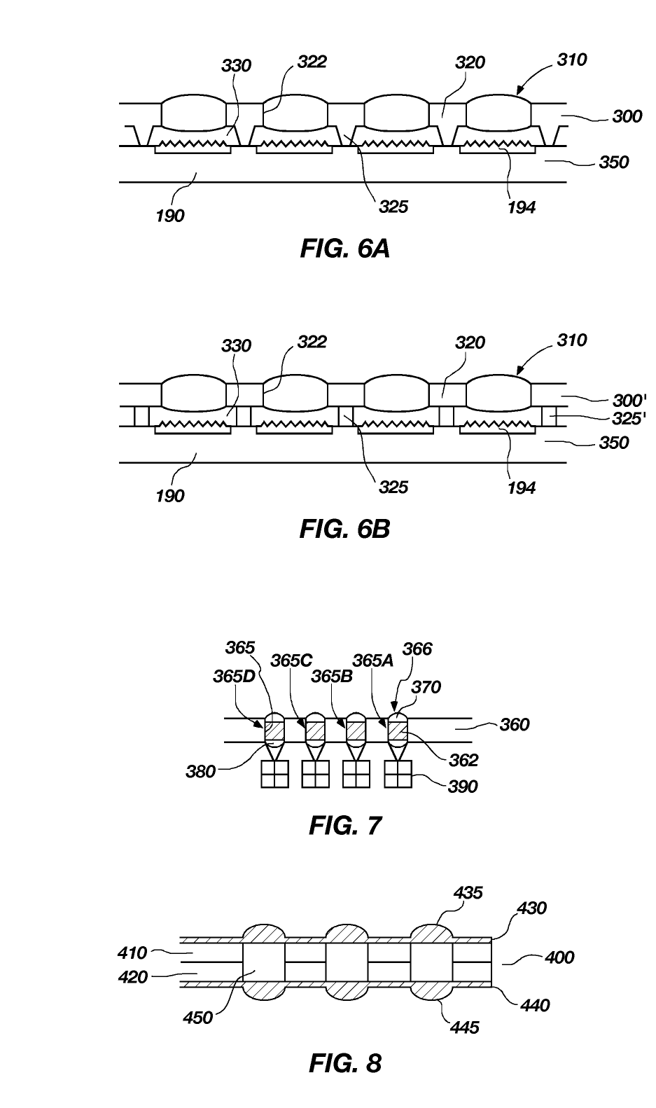

Another embodiment of a wafer-level lens array 300 according to aspects of the present invention is shown in FIG. 6A. The lens array 300 includes lenses 3 10 disposed within vias 322 in a substrate 320. The substrate 320 may include spacers 325, configured as walls for bordering lenses 310 and for positioning the lenses 310 apart from the imager wafer 350 and the optically active regions comprising imager arrays 194 of image sensor dice 190 disposed thereon. Gaps 330 between the image sensor dice 190 and the lenses 310 may be filled with air or a specific gas, or may comprise a vacuum gap. Any suitable material with a refractive index less than that of the lens material may be employed for filling the gap 330. The spacers 325 may be formed by anisotropically or isotropically etching material from the substrate 320 using conventional photolithographic and etching techniques prior to forming the lenses 310 in the vias. Alternatively, the spacers 325 may be patterned onto the substrate 320. The spacers 325 may comprise a patterned layer of adhesive, a preformed grid of adhesive elements, or a spacer wafer.

FIG. 613 depicts a lens array 300′ aligned with a spacer wafer 325′ and stacked with the imager wafer 350 to form a lens system. The spacer wafer 325′ may comprise a substrate 100A having vias 120 therethough, as shown in FIG. 1B. The spacer wafer 325′ may be formed, for example, by wet etching, dry etching, powder blasting, water jet, or laser ablation. The spacers 325, 325′ define the distance between the lens wafer or lens array 300, 300′ and another lens wafer, or the imager wafer 350 that may be required for a certain optical design.

Another embodiment of a wafer-level lens array 360 according to the present invention is shown in FIG. 7. The lens array 360 includes microlenses 366 disposed within vias 365 in a substrate. Each microlens 366 may be formed over and correspond to a pixel 390 of an imager array of an image sensor die 190. The microlenses 366 each may be configured to focus radiation impinging on the exposed outer surface thereof onto a focal plane in which the corresponding pixel 390 is disposed. The microlenses 366 may each comprise a first lens portion 370, a central filter portion 365A, 365B, 365C, 365D, and a second lens portion 380. The first and second lens portions 370, 380 may comprise, for example, a polymer material that is formulated and configured to exhibit the desired optical properties.

The central filter portions 365A, 365B, 365C, 365D may provide a color filter array (CFA). A CFA may include filters of red, green and blue (RGB) or cyan, magenta and yellow (CMY). Each filter may provide an electromagnetic radiation filter positioned over a single pixel 390 so as to selectively filter the radiation impinging on each respective pixel 390.

The wafer-level lens array 360 may include a plurality of color filter arrays, each color filter array corresponding to an imager array of an image sensor die 190 formed on TWI imager wafer 180. By way of example and not limitation, the filters 365A, 365B, 365C, 365D may be configured in a so-called “GRGB Bayer pattern” in which one half of the individual filters are configured to allow green light to pass through the lens while preventing other wavelengths of light from passing through the lens (the “green” or “G” filters), one fourth of the individual filters are configured to allow red light to pass through the lens while preventing other wavelengths of light from passing through the lens (the “red” or “R” filters), and one fourth of the individual filters are configured to allow blue light to pass through the lens while preventing other wavelengths of light from passing through the lens (the “blue” or “B” filters). Imager devices according to embodiments of the present invention are not limited to such color filter array patterns, and the color filter array may comprise any pattern of individual filtering lenses. The green, red, and blue lenses may be interspersed amongst each other in a substantially symmetric pattern. In this configuration, the pixels 390 corresponding to the green filters in the color filter array (the “green pixels”) will detect green light, the pixels 390 corresponding to the red filters in the color filter array (the “red pixels”) will detect red light, and the pixels 390 corresponding to the blue filters in the color filter array (the “blue pixels”) will detect the blue light. In this configuration, the signals generated by the combined green, red, and blue pixels 390 may be combined to generate a full color image.

The central filter portions 365A, 365B, 365C, 365D may comprise, for example, a polymer material that is formulated to exhibit the desired optical filtering properties by passing only selected wavelengths of light. Such materials are known in the an and commercially available. The polymer material may be molded within the vias 362. Alternatively, a spin-coating method may be used to deposit the polymer material of the central filter portions 365A, 365B, 365C, 365D. Liquid polyimide may be disposed on the substrate, and the substrate may be rotated at high speeds to spread the fluid to a desired thickness. The layer 430 may be etched to remove the polyimide from non-desired locations.

Yet another embodiment of a lens array 400 according to the present invention is shown in FIG. 8. The lens array 400 includes a first substrate 410 disposed on a second substrate 420. The first and second substrates 410, 420 may be bonded together by any suitable method, for example, fusion bonding, anodic bonding, or with an epoxy. Through-hole vias 450 may be formed in the stacked first and second substrates 410, 420 by any suitable method, for example by etching or laser drilling. Alternatively, vias may be formed in the first substrate 410 and the second substrate 420 prior to stacking.

A layer 430 of lens material, for example polyimide, may be disposed over the first substrate 410. The layer 430 may “tent” over the through-hole vias 450. Tenting describes the ability of fluid, through viscosity and surface tension, to cover, bridge or span an unsupported substrate area, for example a through-hole of an electronic printed circuit board. Methods of tenting polyimide materials over through-holes are known to those of ordinary skill in the art. A spin-coating method may be used to apply the layer 430. Liquid polyimide may be disposed on the first substrate 410, and the substrate 410 may be rotated at high speeds to spread the fluid to a desired thickness. The layer 430 may be etched to form the desired lens configuration 435 over the vias 450. A second layer 440 of lens material may be applied over the second substrate 420 and etched to form the desired lens configuration 445. Air may be trapped within the vias 450 when the second layer 440 is spun over the second substrate 420. The trapped air may support the layers 430, 440 of lens material over the vias 450.

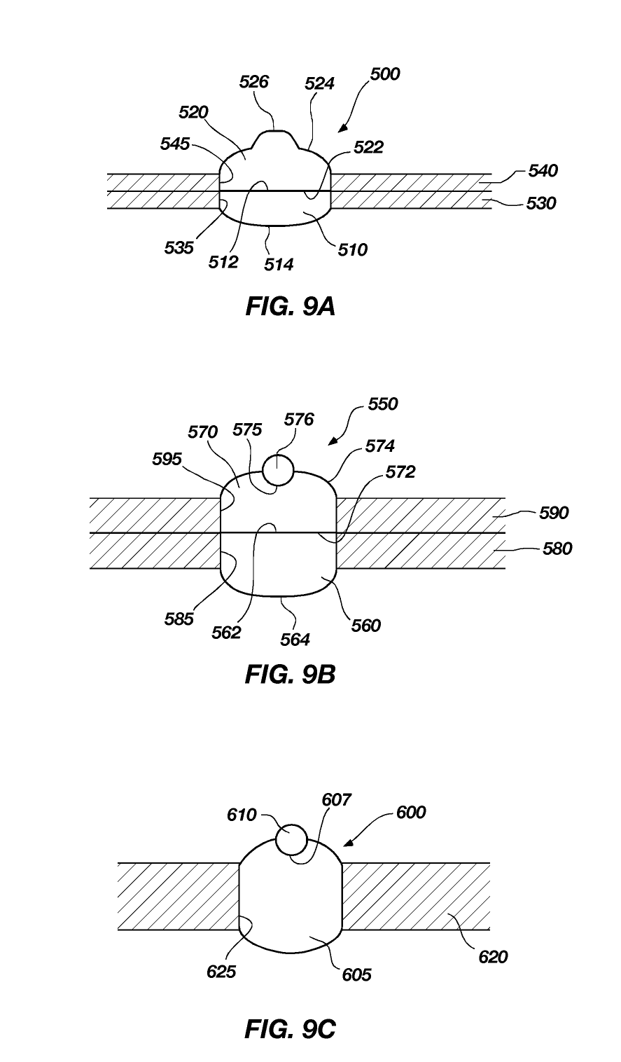

Additional embodiments of lenses according to the present invention are shown in FIGS. 9A through 9C. It may be desirable to have an asymmetric lens to enable a lens configuration having a desired focal length. The lenses shown in FIGS. 9A through 9C are asymmetrical. The lens 500 shown in FIG. 9A may comprise a first portion 510 within a via 535 of a first substrate 530. The first portion 5.10 may be plano-convex, having a substantially planar surface 512, and an opposing, convex surface 514. The lens 500 may further comprise a second portion 520 within a via 545 of a second substrate 540. The second portion 520 may have a substantially planar surface 522, and an opposing surface 524. The opposing surface 524 may be substantially convex with a protrusion 526 extending therefrom. The second substrate 540 may be superimposed upon the first substrate 530, with the vias 535, 545 aligned. The substantially planar surface 512 of the first portion 510 may abut the substantially planar surface 522 of the second portion 520.

The lens portions 510, 520 may be formed in the vias 535, 545 according to the methods described hereinabove. For example, the lens portions 510, 520 may each be formed within the vias 535, 545 by molding. The protrusion 526 on the opposing surface 524 of the second portion 520 may be formed in the mold, or the surface 524 may be etched subsequent to molding to form the protrusion 526. The first and second substrates 530, 540 and the first and second lens portions 510, 520 may be affixed to one another, for example, using fusion bonding, anodic bonding, or an epoxy.

The lens 550 shown in FIG. 9B may comprise a first portion 560 within a via 585 of a first substrate 580. The first portion 560 may be plano-convex, having a substantially planar surface 562, and an opposing, convex surface 564. The lens 550 may further comprise a second portion 570 within a via 595 of a second substrate 590. The second portion 570 may have a substantially planar surface 572, and an opposing surface 574. The opposing surface 574 may be substantially convex with a cavity 575 therein. A smaller, third portion 576 may be partially disposed within the cavity 575, and protrude therefrom. The second substrate 590 may be superimposed upon the first substrate 580, with the vias 585, 595 aligned. The substantially planar surface 562 of the first portion 560 may abut the substantially planar surface 572 of the second portion 570.

The lens portions 560, 570 may be formed in the vias 585, 595 according to the methods described hereinabove. For example, the lens portions 560, 570 may each be formed within the vias 585, 595 by molding. The protruding third portion 576 on the opposing surface 574 of the second portion 570 may be formed subsequent to the second portion 570, using another mold, or the protruding third portion 576 may be preformed, and may be affixed within the cavity 575. The first and second substrates 580, 590 and the first and second lens portions 560, 570 may be affixed to one another, for example, using fusion bonding, anodic bonding, or an epoxy.

Turning to FIG. 9C, another asymmetric lens 600 is shown. The lens 600 may comprise a first portion 605 and a second portion 610. The first portion 605 may comprise opposing, substantially convex surfaces. One surface includes a cavity 607. The second portion 610 may be at least partially disposed within the cavity 607. The lens 600 may be disposed within a via 625 of a substrate 620. The lens 600 may be formed, for example, by molding.

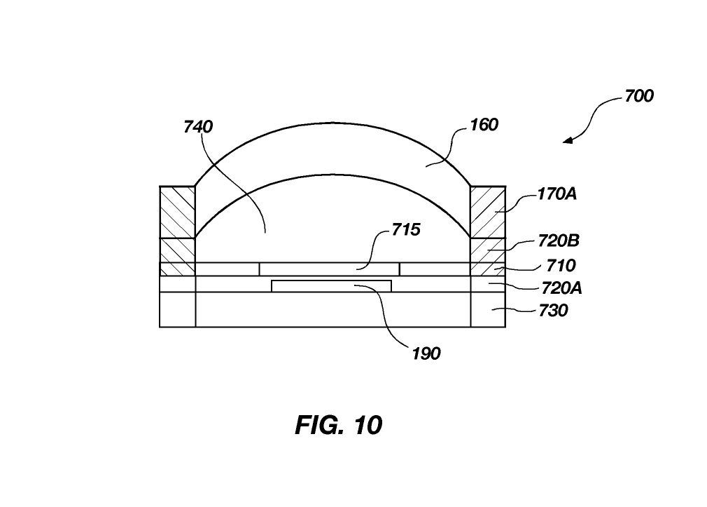

FIG. 10 shows another embodiment of a semiconductor package 700 according to the present invention. The image sensor device 190 may be disposed on a substrate 730. A lens substrate 710 including a microlens array 715 may be stacked above the semiconductor device. The microlens array 715 may include a plurality of microlenses 366 as shown in FIG. 7 and described hereinabove. The microlenses of the microlens array 715 may include a CFA, or the microlenses may be substantially clear, and a conventional CFA (not shown) may be provided between the microlens array 715 and the semiconductor device 190.

A first spacer 720A may be configured as walls for bordering the semiconductor device 190 and for positioning the microlens array 715 above the substrate 730 and the optically active regions of the image sensor dice 190 disposed thereon. The first spacers 720A may be formed by anisotropically or isotropically etching material from the lens substrate 710 using conventional photolithographic and etching techniques prior to forming the microlens array 715. Alternatively, the first spacer 720A may comprise a patterned layer of adhesive, a preformed grid of adhesive elements, or a portion of another, aligned substrate 100A having vias 120 therethough, as shown in FIG. 18.

A second spacer 720B may be configured as a wall for bordering the microlens array 715 and for positioning the lens 160 apart from the image sensor device 190 and the microlens array 715 disposed thereon. The gap 740 between the image sensor dice 190 and the lens 160 may be filled with air or a specific gas, or may comprise a vacuum gap. Any suitable material with a refractive index less than that of the lens material may be employed for filling the gap 740. The second spacer 720B may be formed by anisotropically or isotropically etching material from the lens substrate 170 using conventional photolithographic and etching techniques prior to forming the lens 160 in the via therethrough. Alternatively, the second spacer 720B may comprise a patterned layer of adhesive, a preformed grid of adhesive elements, or another, aligned substrate 100A having vias 120 therethrough, as shown in FIG. 1B.

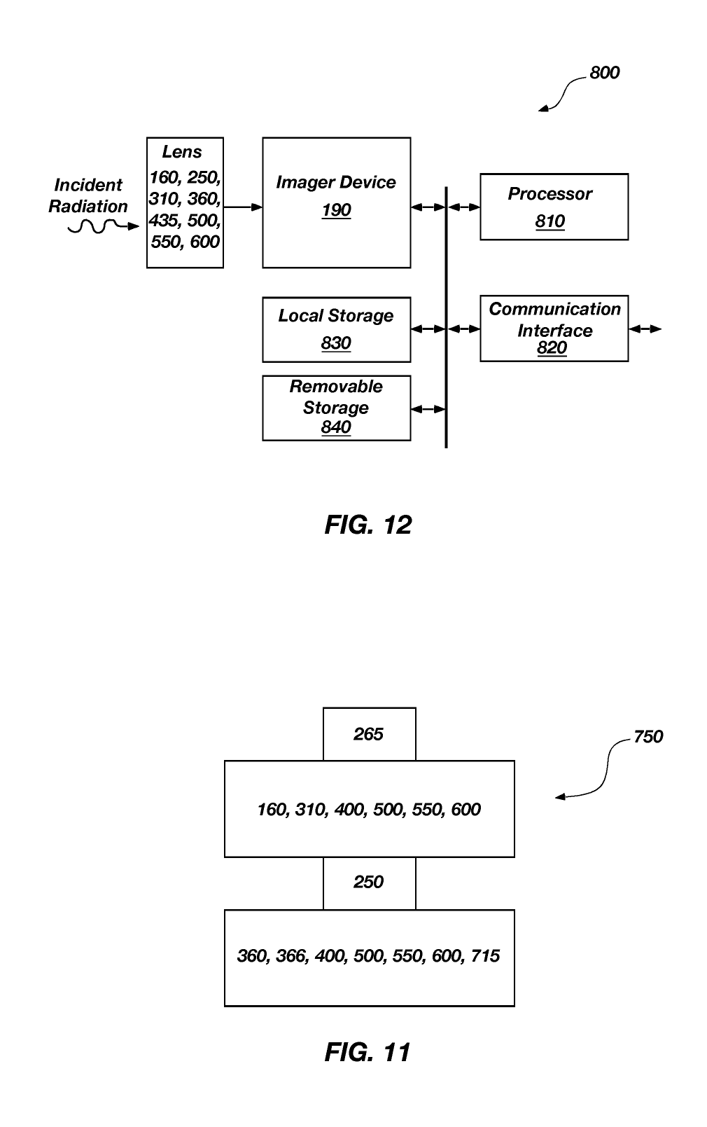

In some embodiments of image sensor packages of the present invention, the imager sensor package may include a lens stack comprising a plurality of lenses or lens arrays 160, 250, 310, 360, 400, 435, 445, 500, 550, 600, 715 stacked one over another so as to form a stack of lenses that collimates and/or focuses radiation onto the optically active region of the semiconductor die 190 as necessary or desired. In other embodiments, the imager sensor package may include microlenses 366 as well as a cover glass 265, a relatively larger lens 160, a field flattening lens 250, or a stack of various combinations of lenses 160, 250, 310, 400, 435, 445, 500, 550, 600, 715. FIG. 11 schematically depicts a lens stack 750 with a cover glass 265, a relatively larger lens 160, 310, 400, 500, 550, or 600, a field flattening lens 250, and a microlens 360, 366, 400, 500, 550, 600, or 715. A lens stack with only two lenses, for example microlenses 360 and a relatively larger lens 160 is within the scope of the present invention.

FIG. 12 is a simplified block diagram illustrating one embodiment of an imaging system 800 according to the present invention. In some embodiments, the imaging system 800 may comprise, for example, a digital camera, a cellular telephone, a computer, a personal digital assistant (PDA), home security system sensors, scientific testing devices, or any other device or system capable of capturing an electronic representation of an image. The imaging system includes an imager device 190 and a lens or stack of lenses comprising two or more of lenses 160, 250, 310, 360, 400, 435, 445, 500, 550, 600, 715 according to various embodiments of the present invention. The imaging system 800 may include an electronic signal processor 810 for receiving electronic representations of images from the imager device 190 and communicating the images to other components of the imaging system 800.

The imaging system 800 also may include a communication interface 820 for transmitting and receiving data and control information. In some embodiments, the imaging system 800 also may include one or more memo devices. By way of example and not limitation, the imaging system may include a local storage device 830 (e.g., a read-only memory (ROM) device and/or a random access memory (RAM) device) and a removable storage device 840 (e.g., flash memory).

The terms “upper,” “lower,” “top” and “bottom” are used for convenience only in this description of the invention in conjunction with the orientations of features depicted in the drawing figures. However, these terns are used generally to denote opposing directions and positions, and not in reference to gravity. For example, semiconductor package 10 may, in practice, be oriented in any suitable direction during fabrication or use.

Although the foregoing description contains many specifics, these should not be construed as limiting the scope of the present invention, but merely as providing illustrations of some exemplary embodiments. Similarly, other embodiments of the invention may be devised which do not depart from the spirit or scope of the present invention. Features from different embodiments may be employed in combination. The scope of the invention is, therefore, indicated and limited only by the appended claims and their legal equivalents, rather than by the foregoing description. All additions, deletions, and modifications to the invention, as disclosed herein, which fall within he meaning and scope of the claims are to be embraced thereby.

1. A method for forming a lens, comprising:
aligning at least one mold platen with a substrate having a plurality of vias formed therethrough;
introducing a flowable material within each of the vias and in contact with the mold platen; and
solidifying the fluid material to form a lens within each via.

2. The method of claim 1, wherein aligning the at least one mold platen comprises aligning a first mold platen having a plurality of concave portions thereon.

3. The method of claim 2, wherein aligning the mold platen comprises aligning each concave portion of the first mold platen with a via of the plurality of vias through the substrate.

4. The method of claim 2, wherein aligning the mold platen further comprises aligning a second mold platen having a plurality of convex portions thereon.

5. The method of claim 4, wherein aligning the mold platen comprises aligning each convex portion of the second mold platen with a via of the plurality of vias through the substrate.

6. The method of claim 2, wherein aligning the mold platen further comprises aligning a second mold platen having a substantially planar surface facing the substrate.

7. The method of claim 1, wherein introducing a flowable material comprises introducing a polymer material.

8. The method of claim 1, wherein introducing a fluid material comprises introducing a material configured to exhibit optical color filtering properties.

9. The method of claim 1, wherein aligning at least one mold platen with a substrate comprises aligning at least one mold platen with a wafer of a silicon or a borosilicate material.

10. The method of claim 1, further comprising etching the substrate to provide spacers adjacent each via.

11. The method of claim 1, wherein aligning at least one mold platen with a substrate comprises aligning at least one mold platen with a substrate having a plurality of vias formed therethrough corresponding to the pixels of an optically active semiconductor die.

12. The method of claim 1, wherein aligning at least one mold platen with a substrate comprises aligning at least one mold platen with a substrate having a plurality of vias formed therethrough corresponding to optically active semiconductor dice of an imager wafer.

13. A method for packaging a semiconductor die, comprising:
forming a plurality of lenses, each lens associated with a via of a plurality of vias through a substrate comprising a lens array wafer;
aligning each lenses of the lens array wafer with an imager array of a semiconductor die of a plurality of semiconductor dice of an imager wafer; and
securing the lens array wafer to the imager wafer.

14. The method of claim 13, further comprising:
cutting the wafer and the substrate to singulate each semiconductor die and the lens secured thereon to form a semiconductor die package.

15. The method of claim 13, wherein securing the lens wafer to the imager wafer comprises bonding by one of fusion bond, anodic bond, and epoxy.

16. The method of claim 13, wherein the imager array of the semiconductor die comprises an optically active region on the surface thereof.

17. The method of claim 16, wherein the plurality of semiconductor dice each comprise one of a CMOS imager and a CCD imager.

18. The method of claim 13, wherein forming a plurality of lenses comprises:
aligning a mold platen with the substrate;
introducing a flowable material within the vias of the substrate; and
solidifying the fluid material to form a lens within each via.

19. The method of claim 13, wherein forming a plurality of lenses comprises forming a polymer lens by injection molding.

20. The method of claim 19, wherein forming a plurality of lenses comprises fabricating the lenses by placing the substrate having vias therethrough into a mold platen defining an array of concave cavities with vias of the substrate adjacent the concave cavities of the mold platen, injecting polymeric molding material into the mold, curing the polymeric material, and removing the substrate from the mold.

21. The method of claim 13, further comprising etching the substrate to form a plurality of spacers.

22. An image sensor package, comprising:
a semiconductor die having an optically active region thereon;
a substrate disposed adjacent the optically active region, the substrate having a plurality of vias therethrough; and
a plurality of lenses, each lens associated with a via of the substrate.

23. The image sensor package of claim 22, further comprising a color filter array comprising:
a filter material disposed in some of the vias of the substrate, the filter material configured to exhibit desired optical filtering properties; and
at least a second filter material disposed in other vias of the substrate, the at least a second filter material configured to exhibit desired optical filtering properties which are different than the desired optical filtering properties of the filter material.

24. The image sensor package of claim 22, wherein each of the plurality of lenses is disposed within the vias.

25. The image sensor package of claim 22, wherein each lens of the plurality of lenses tents over the associated via.

26. The image sensor package of claim 22, wherein at least one lens of the plurality of lenses includes a concave surface and a convex surface.

27. The image sensor package of claim 22, wherein at least one lens of the plurality of lenses includes a protrusion extending from a surface thereof.

28. The image sensor package of claim 27, wherein the protrusion is integral with the lens.

29. The image sensor package of claim 27, wherein the protrusion is attached to the lens.

30. The image sensor package of claim 22, further comprising a second substrate adjacent to the substrate and having a second plurality of vias therethrough, the second plurality of vias substantially aligned with the plurality of vias.

31. The image sensor package of claim 30, wherein each lens of the plurality of lenses includes a first portion associated with the substrate, and a second portion associated with the second substrate.

32. An imaging system, comprising:
an image sensor package, comprising:
a semiconductor die having an optically active region thereon;
a substrate disposed adjacent the optically active region, the substrate having at least one via therethrough; and
at least one lens associated with a via of the substrate;
an electronic signal processor in communication with the image sensor package;
a communication interface in communication with the electronic signal processor; and
a local storage device in communication with the electronic signal processor.

33. The imaging system of claim 32, wherein the imaging system comprises one of a digital camera, camera (cell) phone, PDA, home security system, endoscope, optical storage apparatus and scientific testing apparatus.

34. An image sensor package, comprising:
a first substrate;
an optically active semiconductor die attached to the first substrate;
a second substrate having a via therethrough and integral spacers attached to the first substrate;
a lens disposed within the via.

35. The image sensor package of claim 34, further comprising at least a third substrate having a via therethrough disposed on the second substrate, and at least a second lens disposed within the via of the third substrate.

36. The image sensor package of claim 34, wherein the lens includes a concave surface and a convex surface.

37. The image sensor package of claim 34, wherein the lens includes a protrusion extending from a surface thereof.

38. The image sensor package of claim 37, wherein the protrusion is integral with the lens.

39. The image sensor package of claim 37, wherein the protrusion is attached to the lens.

40. An image sensor package, comprising:
a first substrate;
an optically active semiconductor die attached to the first substrate;
a second substrate attached to the first substrate;
a third substrate substantially aligned with the second substrate and attached thereto;
a via extending through the second substrate and the third substrate and substantially aligned with an optically active region of the optically active semiconductor die;
a first lens tenting over the via and attached to a surface of the second substrate; and
a second lens tenting over the via and attached to a surface of the third substrate.
